(19) United States
(12) Patent Application Publication
(10) Pub. No.: US 2026/0333831 A1
(43) Pub. Date: Oct. 22, 2026

(54) CFET STRUCTURE WITH SEPARATE N-MOS AND P-MOS PROCESSES VIA AN ESL

(71) Applicant: Taiwan Semiconductor Manufacturing Co., Ltd., Hsinchu (TW)

(72) Inventors: Chih-Pin Lin, Hsinchu (TW); Zhi-Chang Lin, Zhubei (TW)

(21) Appl. No.: 19/721,701

(22) Filed: Jun. 26, 2026

Related U.S. Application Data
(63) Continuation of application No. 19/014,532, filed on Jan. 9, 2025.
(60) Provisional application No. 63/699,915, filed on Sep. 27, 2024.

(51) Int. Cl. H10D 84/01; H10D 84/83

(52) U.S. Cl. CPC H10D 84/013; H10D 84/0149; H10D 84/8311; H10D 84/832

(57) ABSTRACT

A method includes forming a multilayer stack comprising a lower multilayer stack over a substrate, a dielectric etch stop layer over the lower multilayer stack, and an upper multilayer stack over the dielectric etch stop layer. The method further includes etching the multilayer stack to form an alignment mark trench, performing a first etching process on the upper multilayer stack to form upper multilayer stack portions, and forming an upper transistor based on the upper multilayer stack portions. The substrate is removed to reveal the lower multilayer stack. The method further includes performing a second etching process on the lower multilayer stack to form lower multilayer stack portions. The first and the second etching processes are performed using the dielectric etch stop layer to stop the respective etching processes, and using the alignment mark trench for alignment. A lower transistor is formed based on the lower multilayer stack portions.

### PRIORITY CLAIM AND CROSS-REFERENCE

This application is a continuation of U.S. Patent Application No. 19/014,532 filed on Jan. 9, 2025, which application claims the benefit of the provisionally filed U.S. Patent Application No. 63/699,915, filed on Sep. 27, 2024, which applications are hereby incorporated herein by reference.

### BACKGROUND

Complementary Field-Effect Transistors (CFETs) are being developed to meet the increasing demanding requirement for increasing the density of transistors in integrated circuits. CFETs are thus developed. A CFET includes a lower transistor and an upper transistor overlapping the lower transistor. The lower transistors and upper transistors of multiple CFETs may be interconnected to form functional circuits.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A, 1B-1, 1B-2-17 illustrate the views of intermediate stages in the formation of Complementary Field-Effect Transistors (CFETs) in accordance with some embodiments.

FIG. 18 illustrates several CFETs with different combinations of CFETs in accordance with some embodiments.

FIG. 19 illustrates a process flow for forming CFETs in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Complementary Field-Effect Transistors (CFETs) including upper FETs (alternatively referred to as transistors) and lower FETs and the formation methods are provided. An alignment mark trench is formed by etching a wafer. A front-side formation process is performed from the front side of the wafer to form upper FETs. A backside formation process is performed from the backside of the wafer to form lower FETs. Both of the upper FETs and the lower FET may be formed by using the alignment mark trench and the features formed therein as alignment marks. Accordingly, the lower FETs may be accurately aligned with the upper FETs vertically to form CFETs. Through this process, the source/drain recesses, in which the source/drain regions are formed, have reduced aspect ratios, and hence may be free from the problems that are likely to occur if the aspect ratios are high.

Although the example embodiments use GAA FETs as the upper FETs and the lower FETs, the embodiments may also be applied to the CFETs comprising other FETs such as Fin Field-Effect Transistors (FinFETs), planar transistors, the like, or the combinations of the GAA FETs, FinFETs, and planar transistors. The Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

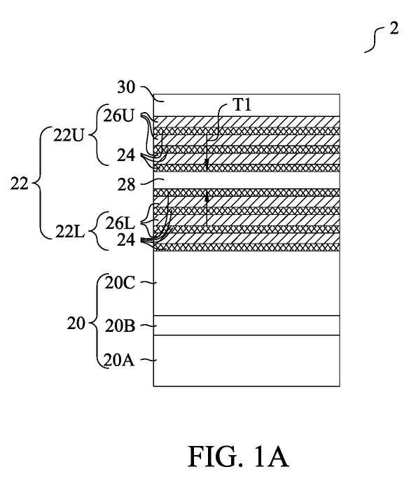

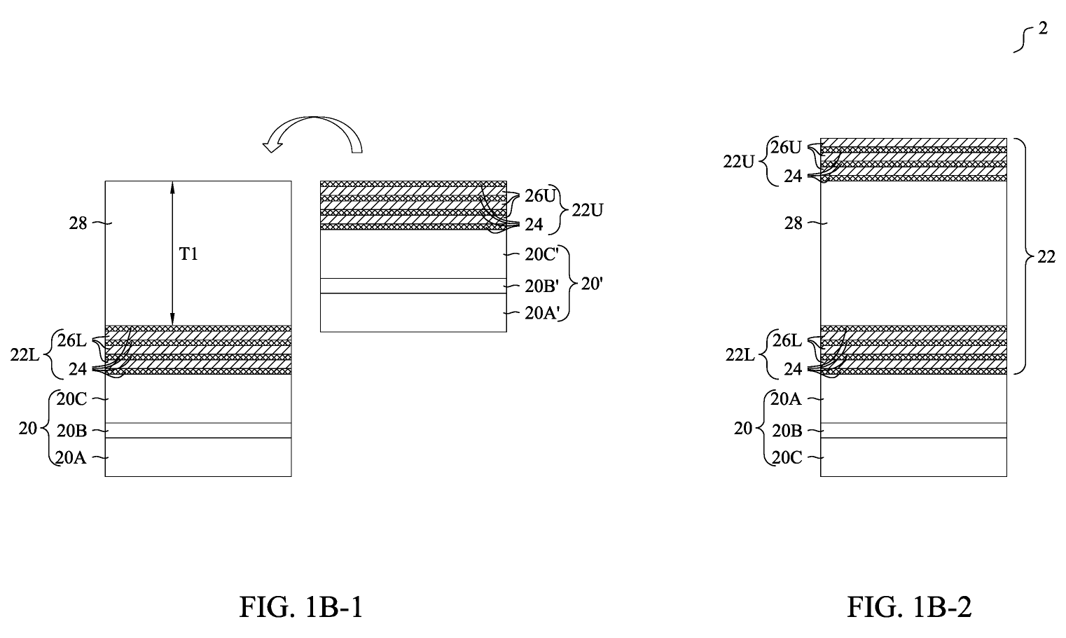

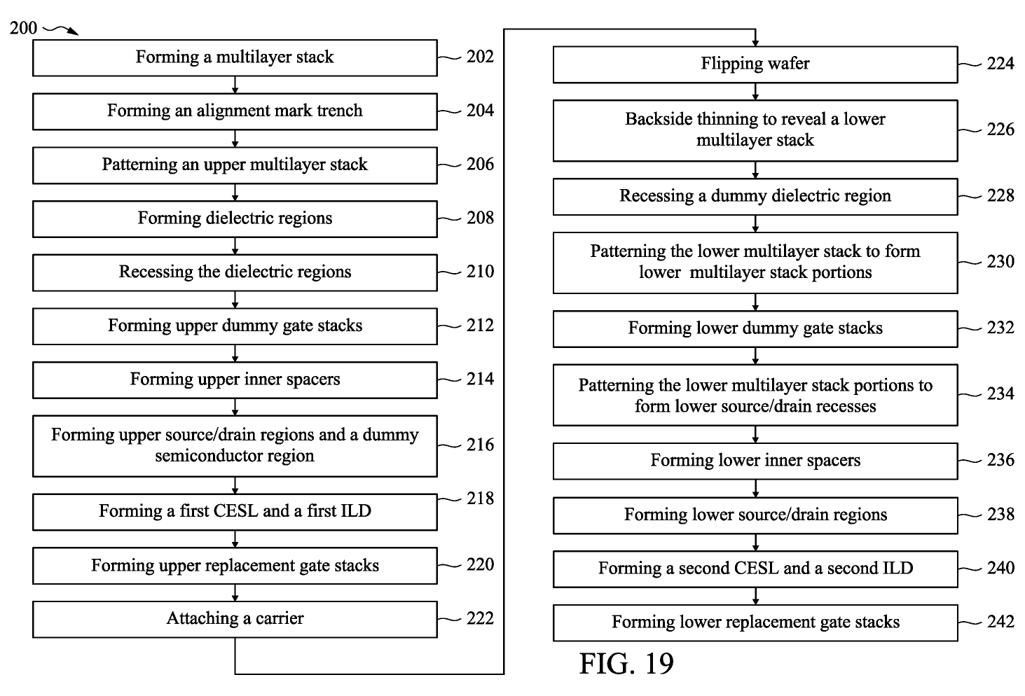

FIGS. 1A, 1B-1, and 1B-2-18 illustrate the cross-sectional views of intermediate stages in the formation of CFETs in accordance with some embodiments. The corresponding processes are also reflected schematically in the process flow 200 as shown in FIG. 19.

Referring to FIG. 1A, wafer 2, which includes substrate 20, is provided. In accordance with some embodiments, substrate 20 is a bulk substrate formed of a homogeneous semiconductor material such as silicon. In accordance with alternative embodiments, as shown in FIG. 1A, substrate 20 is a composite substrate having a composite structure. The composite structure may include semiconductor layers 20A and 20C, which may be silicon layers, and stop layer 20B, which may be formed of or comprise a semiconductor material such as silicon germanium. Alternatively, stop layer 20B may comprise a dielectric material such as silicon nitride, a silicon oxide, or the like.

A multilayer stack 22 is formed over the substrate 20. The respective process is illustrated as process 202 in the process flow 200 as shown in FIG. 19. The multilayer stack 22 includes alternating dummy semiconductor layers 24 and semiconductor layers 26 (including lower semiconductor layers 26L and upper semiconductor layers 26U). Lower semiconductor layers 26L and upper semiconductor layers 26U are for forming lower FETs and upper FETs, respectively. Multilayer stack 22 include upper multilayer stack portion 22U and lower multilayer stack portion 22L.

The dummy semiconductor layers 24 are formed of a semiconductor material, which may be selected from the candidate semiconductor materials of the substrate 20. The semiconductor layers 26 (including the lower semiconductor layers 26L and upper semiconductor layers 26U) are formed of one or more semiconductor material(s) different from the material of dummy semiconductor layers 24. The semiconductor material(s) may also be selected from the candidate semiconductor materials of the substrate 20. In some embodiments, dummy semiconductor layers 24 are formed of or comprise silicon germanium, and semiconductor layers 26 are formed of silicon.

Dielectric layer 28 is formed between upper multilayer stack portion 22U and lower multilayer stack portion 22L. Dielectric layer 28 may be in contact with an overlying dummy semiconductor layer 24 and an underlying dummy semiconductor layer 24.

In accordance with some embodiments, the lower semiconductor layers 26L are formed of a same semiconductor material as the upper semiconductor layers 26U. For example, both of the lower semiconductor layers 26L and the upper semiconductor layers 26U may comprise silicon, which may be free from germanium.

In accordance with alternative embodiments, the lower semiconductor layers 26L are formed of a semiconductor material different from the semiconductor material of the upper semiconductor layers 26U. For example, first semiconductor layers, which may be either the lower semiconductor layers 26L or the upper semiconductor layers 26U, may comprise silicon germanium, while the second semiconductor layers, which may be either the upper semiconductor layers 26U or the lower semiconductor layers 26L, may comprise silicon (free from germanium). In accordance with alternative embodiments, the first semiconductor layers may comprise germanium (free from silicon) or silicon germanium, and the second semiconductor layers may comprise silicon germanium with a lower germanium atomic percentage than the first semiconductor layers.

In accordance with some embodiments, the lower semiconductor layers 26L or upper semiconductor layers 26U that are used for forming PFETs comprise germanium, or silicon germanium with a higher germanium atomic percentage, while the semiconductor layers 26L or 26U that are used for forming NFETs comprise silicon, or silicon germanium with a lower germanium atomic percentage than the ones for forming PFETs.

Dielectric layer 28 may comprise a dielectric material and may have an amorphous structure or a crystalline structure. In subsequent processes, dielectric layer 28 is used as an etch stop layer and hence is alternatively referred to as (dielectric) etch stop layer 28.

In accordance with some embodiments, the structure shown in FIG. 1A is deposited layer-by-layer on substrate 20. For example, the lower semiconductor layers 26L and the dummy semiconductor layers 24 in lower multilayer stack portions 22L are first grown. Next, dielectric layer 28 is epitaxially grown over a dummy semiconductor layers 24 and thus has a crystalline structure. In accordance with some embodiments, dielectric layer 28 comprises a dielectric material (such as Beryllium oxide (BeO)) that is capable of forming a lattice (crystalline) structure.

In accordance with these embodiments, the thickness T1 of the dielectric layer 28 may be small when the dielectric layer 28 is formed through epitaxy. For example, thickness T1 may be in the range between about 10nm and about 50nm.

After the epitaxy of dielectric layer 28, the upper semiconductor layers 26U and the adjoining dummy semiconductor layers 24 in upper multilayer stack portion 22U are epitaxially grown layer-by-layer. Multilayer stack 22 is thus formed.

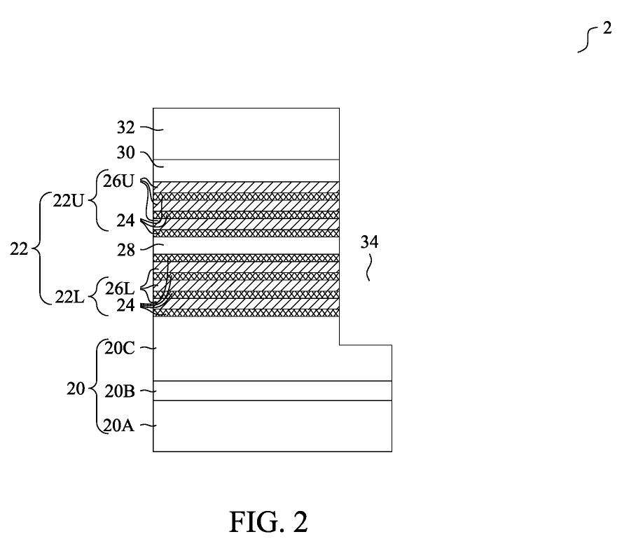

In accordance with alternative embodiments, instead of forming the entire multilayer stack 22 layer-by-layer through epitaxy, the upper multilayer stack portion 22U and the lower multilayer stack portion 22L are formed separately as separate wafers, and are bonded to form the wafer 2 as shown in FIG. 1A. For example, FIGS. 1B-1 and 1B-2 illustrate an example formation process. As shown in FIG. 1B-1, lower semiconductor layers 26L and dummy semiconductor layers 24 in lower multilayer stack portion 22L are grown starting from semiconductor substrate 20.

Dielectric layer 28 is then deposited over lower multilayer stack portion 22L, hence forming a first wafer. In accordance with some embodiments, dielectric layer 28 comprises a silicon-containing dielectric material such as silicon oxide, silicon nitride, silicon oxynitride, silicon oxycarbide, or the like, or combinations thereof. Dielectric layer 28 may have an amorphous structure.

In order to have a high bonding strength, dielectric layer 28 may be a thick layer. With a thick dielectric layer 28, which may have lower thermal conductivity than the semiconductor materials in multilayer stack portions 22U and 22L, however, the thermal dissipation through dielectric layer 28 may be adversely reduced. Accordingly, the thickness T1 of dielectric layer 28 is controlled to be great enough in order have a good bonding strength, but small enough in order to not affect thermal dissipation too much. For example, the thickness T1 may be greater than about 500nm and may be in the range between about 500nm and about 800nm.

FIG. 1B-1 further illustrates the formation of upper multilayer stack portion 22U in a second wafer. The upper semiconductor layers 26U and dummy semiconductor layers 24 in upper multilayer stack portion 22U are epitaxially grown over substrate 20’. In accordance with some embodiments, substrate 20’ has a similar or a same structure as substrate 20. For example, substrate 20’ may be a composite substrate having a composite structure. The composite structure may include semiconductor layers 20A’ and 20C’, which may be silicon layers, and stop layer 20B’, which may be formed of or comprise a semiconductor material such as a silicon germanium, or may be formed of or comprise a dielectric material such as silicon nitride, silicon oxide, or the like.

Referring to FIG. 1B-2, the second wafer is bonded to the first wafer by bonding substrate 20’ and the upper multilayer stack portion 22U to dielectric layer 28. The bonding may be achieved through fusion bonding, in which Si-O-Si bonds are formed.

Next, a thinning process is performed. The thinning may be performed through a Chemical Mechanical Polish (CMP) process and/or an etching process. For example, a CMP process may be performed to remove semiconductor layer 20A’, with stop layer 20B’ being used as the CMP stop layer. An etching process or a CMP process may then be performed to remove stop layer 20B’ and semiconductor layer 20C’, with the CMP process or the etching process stopping on a dummy semiconductor layer 24. The exposed dummy semiconductor layer 24 is then removed, exposing a semiconductor layer 26U. The resulting structure is also shown in FIG. 1A.

Further referring to FIG. 1A, hard mask 30 is formed. In accordance with some embodiments, hard mask 30 comprises a material that may endure the subsequent thermal process. In accordance with some embodiments, hard mask 30 comprises silicon nitride, titanium nitride, boron nitride, or the like.

Referring to FIG. 2, etching mask 32 is formed and patterned. Etching mask 32 may comprise a photoresist, and may be a single-layer etching mask, a double-layer etching mask, or a tri-layer etching mask. Next, an etching process is performed to etch multilayer stack 22 and substrate 20, so that trench 34 is formed. The respective process is illustrated as process 204 in the process flow 200 as shown in FIG. 19. Trench 34 and the features to be formed therein are to be used as alignment marks in subsequent processes and hence trench 34 is also referred to as alignment mark trench 34. In accordance with some embodiments, there are a plurality of trenches 34 formed, and the top-view patterns of trenches 34 can be uniquely identified and thus may be used for aligning lower FETs to upper FETs.

In accordance with some embodiments, trench 34 penetrates through multilayer stack 22, and extends into substrate 20 such as semiconductor layer 22C. Alternatively, trench 34 may also extend into stop layer 20B, and may or may not extend into semiconductor layer 22A.

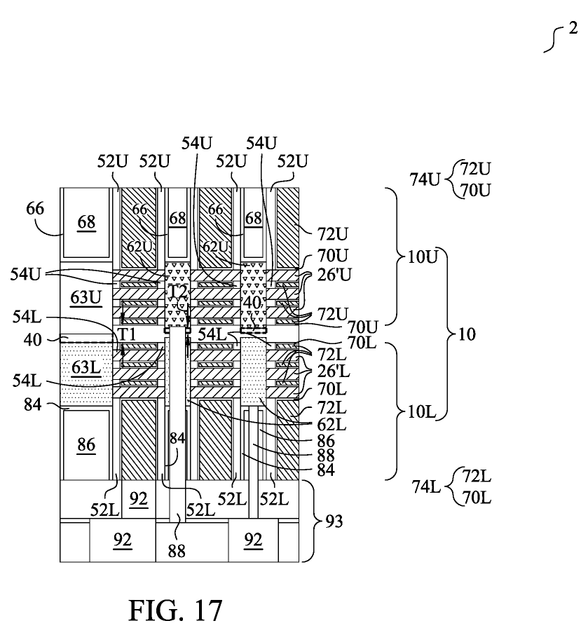

In accordance with some embodiments, as illustrated in the subsequently formed structure as shown in FIG. 17, trench 34 and the resulting features 63U, 63L, and 40 (which may be used as alignment marks) formed therein are immediately next to a CFET. In accordance with alternative embodiments, the trench 34 and the resulting alignment marks therein are formed in locations of wafer 2 that are spaced apart from CFETs. For example, the trench 34 and the resulting alignment marks may be formed in scribe lines, partial dies (the dies not having rectangular shapes) that are at the edge of wafer 2, or inside device dies (in which the CFETs are located) but are spaced apart from CFETs.

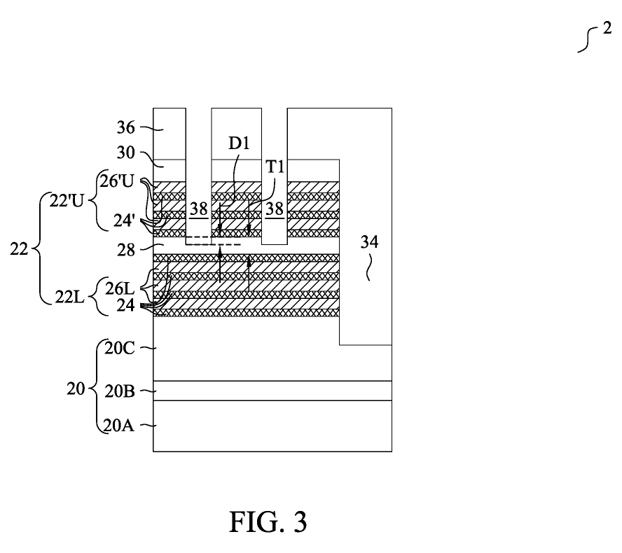

After the formation of trench 34, etching mask 32 is removed. Next, as shown in FIG. 3, etching mask 36 is formed and patterned. The upper multilayer stack portion 22U is patterned in an anisotropic etching process to form source/drain recesses 38 in the upper multilayer stack portions 22U. The respective process is illustrated as process 206 in the process flow 200 as shown in FIG. 19.

The remaining portions of the upper multilayer stack portion 22U are referred to as upper multilayer stack portions 22’U (also referred to as patterned upper multilayer strips) hereinafter, which are referred to using the corresponding reference number followed by a “’” sign. When viewed in a top view of wafer 2, upper multilayer stack portions 22’U form a plurality of elongated strips that are separated by source/drain recesses 38.

Upper multilayer stack portions 22’U also form a plurality of protruding fins protruding higher than dielectric layer 28, with the sidewalls and the top surfaces of the protruding fins being exposed. The protruding fins includes dummy nanostructures 24’ and upper semiconductor layers 26’U (also referred to as semiconductor nanostructures 26’U), whose sidewalls are also exposed.

The etching is performed using dielectric layer 28 as an etching stop layer. Due to the over-etching, source/drain recesses 38 extend into dielectric layer 28 for depth D1. In accordance with some embodiments, the ratio D1/T1 may be in the range between about 0.05 and about 0.2, for example, wherein thickness T1 is measured at a location directly underlying upper multilayer stack portions 22’U. After the etching process, etching mask 36 is removed.

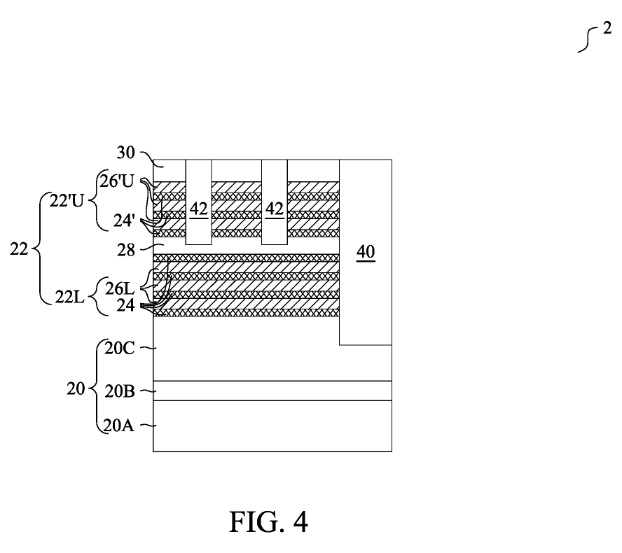

Next, referring to FIG. 4, a dielectric material(s) is filled into trench 34 and source/drain recesses 38, forming dielectric regions 40 (alternatively referred to as a dummy dielectric region) and 42, respectively. The respective process is illustrated as process 208 in the process flow 200 as shown in FIG. 19. In accordance with some embodiments, the formation of dielectric regions 40 and 42 comprises performing a bottom-up deposition process or a conformal deposition process to deposit a dielectric material, and performing a planarization process such as a CMP process or a mechanical polish process to level the top surfaces of hard mask 30 and dielectric regions 40 and 42.

The deposition method of the dielectric material may comprise Flowable Chemical Vapor Deposition (FCVD), Atomic Layer Deposition (ALD), Chemical Vapor Deposition (CVD), or the like. Dielectric regions 40 and 42 may comprise silicon oxide, silicon nitride, silicon oxynitride, silicon carbide, or the like, or combinations thereof. The material of dielectric regions 40 and 42 may be different from (or the same as) the material of dielectric layer 28.

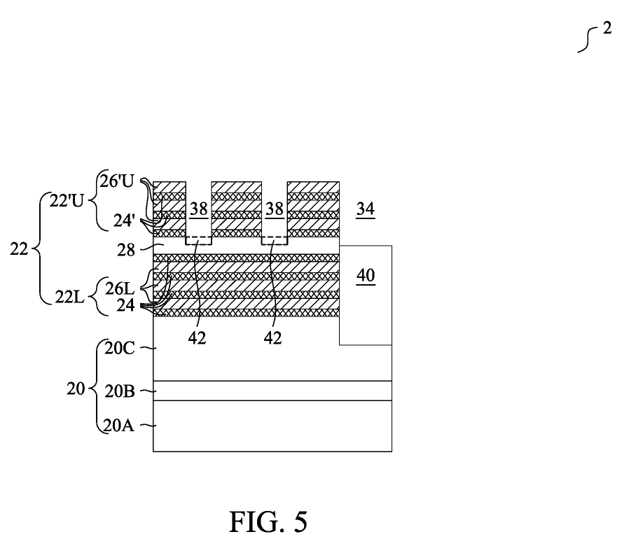

Dielectric regions 40 and 42 are then etched back, and the resulting structure is shown in FIG. 5. The respective process is illustrated as process 210 in the process flow 200 as shown in FIG. 19. In accordance with some embodiments, the etch-back process is performed through an isotropic etching process, which may be a dry etching process or a wet etching process. Alternatively, an anisotropic etching process is performed. After the etch-back process, the top surface of the remaining portion of dielectric region 40 may be at a level between the top surface and the bottom surface of dielectric layer 28.

In accordance with some embodiments, dielectric regions 42 are fully removed, and the top surface of dielectric layer 28 is exposed. In accordance with alternative embodiments, one or a plurality of dielectric regions 42 may have some portions left in dielectric layer 28. The corresponding remaining dielectric regions 42 are shown as being dashed to indicate that they may be removed or may remain in the final structure. For example, in the embodiments in which the process as shown in FIGS. 1B-1 and 1B-2 is performed, dielectric layer 28 is thick. Accordingly, the over-etch for forming source/drain recesses 38 (FIG. 3) may result in the source/drain recesses 38 to extend deep into dielectric layer 28, and there may be dielectric regions 42 remaining.

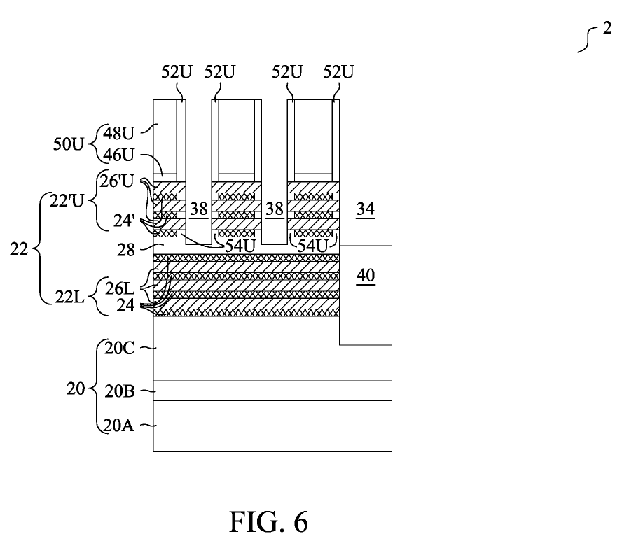

Referring to FIG. 6, dummy gate stacks 50U are formed. The respective process is illustrated as process 212 in the process flow 200 as shown in FIG. 19. Since upper multilayer stack portions 22’U are protruding fins that are over dielectric layer 28, dummy gate stacks 50U are formed on the sidewalls and the top surfaces of the upper multilayer stack portions 22’U. In accordance with some embodiments, dummy gate stacks 50U include dummy dielectric layer 46U contacting the sidewalls (when viewed in another cross-section) and the top surfaces of the upper multilayer stack portions 22’U. Dummy dielectric layer 46U may be formed of or comprise, for example, silicon oxide, silicon nitride, a combination thereof, or the like, and may be deposited or thermally grown according to acceptable techniques.

Dummy gate stacks 50U further comprises dummy gate layer 48U, which are formed over the dummy dielectric layer 46U. The material of dummy gate layer 48U may be conductive or non-conductive and may be selected from a group including amorphous silicon, polycrystalline-silicon (polysilicon), poly-crystalline silicon-germanium (poly-SiGe), or the like. Dummy gate layer 48U is planarized, for example, in a CMP process.

While not shown, each dummy gate stack 50U may further include a mask layer formed over the planarized dummy gate layer 48U. The mask layer may be formed of silicon nitride, silicon oxynitride, or the like. A patterning process is performed to pattern the mask layer, the dummy gate layer 48U, and the dummy dielectric layer 46U. The remaining portions of the mask layer, dummy gate layer 48U, and dummy dielectric layer 46U form dummy gate stacks 50U.

As also shown in FIG. 6, gate spacers 52U are formed over the upper multilayer stacks 22’U and on exposed sidewalls of dummy gate stacks 50U. The respective process is illustrated as process 214 in the process flow 200 as shown in FIG. 19. The gate spacers 52U may be formed by conformally forming one or more dielectric layers and subsequently etching the dielectric layers anisotropically. The applicable dielectric materials may include silicon oxide, silicon nitride, silicon oxynitride, silicon oxycarbonitride, or the like, which may be formed by a deposition process such as CVD, ALD, or the like.

In accordance with some embodiments, since the outer edges of upper multi-layer stack portions 22’U may not be vertically aligned to, and may laterally extend beyond, the corresponding edges of gate spacers 52U, an anisotropic etching process may be performed to further trim upper multilayer stack portion 22’U, so that the outer edge of upper multilayer stack portion 22’U are vertically aligned to the outer edges of gate spacers 52U.

In accordance with alternative embodiments, the dielectric regions 40 and 42 are formed after the formation of the dummy gate stacks 50U and gate spacers 52U. The formation process thus may include, after the structure as shown in FIG. 1A is formed, patterning the upper multilayer stack 22U to form multilayer stack portions 22’U, forming dummy gate stacks 50U and gate spacers 52U, etching the upper multilayer stack portions 22’U to form source/drain recesses 38, and etching the upper multilayer stack portions 22’U and substrate 20 to form alignment mark trench 34.

Dielectric regions 40 and 42 are then formed through a deposition process and a planarization process. The planarization process may use the mask layer in the dummy gate stacks 50U as a stop layer. An etch-back process is then performed, forming the structure shown in FIG. 6 (except upper inner spacers 54U have not been formed at this time). Through this process, the outer edge of upper multilayer stack portion 22’U are vertically aligned to the outer edges of gate spacers 52.

In a subsequent process, dummy nanostructures 24’ are laterally recessed, and a dielectric material is filled into the respective recesses to form upper inner spacers 54U, which are dielectric spacers. The resulting structure is also shown in FIG. 6.

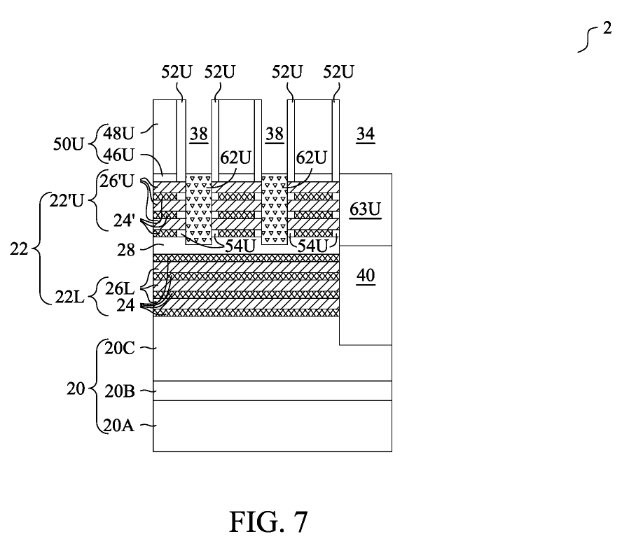

Referring to FIG. 7, upper source/drain regions 62U and dummy semiconductor region 63U are formed in the lower portions of the source/drain recesses 38 (FIG. 5) and alignment mark trench 34, respectively. The respective process is illustrated as process 216 in the process flow 200 as shown in FIG. 19. The upper source/drain regions 62U are in contact with the upper semiconductor layers 26’U. Upper inner spacers 54U electrically insulate the upper source/drain regions 62U from the dummy nanostructures 24’, which will be replaced with replacement gate stacks in subsequent processes. While not shown, air gaps may be (or may not be) formed between upper source/drain regions 62U and dielectric layer 28 (or dielectric region(s) 42, if any is remaining).

The upper source/drain regions 62U are epitaxially grown and have a conductivity type that is suitable for the device type (p-type or n-type) of the upper FETs. When upper source/drain regions 62U are n-type source/drain regions, the respective material may include silicon or carbon-doped silicon, which is doped with an n-type dopant such as phosphorous, arsenic, or the like. When upper source/drain regions 62U are p-type source/drain regions, the respective material may include silicon or silicon germanium, which is doped with a p-type dopant such as boron, indium, or the like. The upper source/drain regions 62U may be in-situ doped, and may be, or may not be, implanted with the corresponding p-type or n-type dopants.

At the time upper source/drain regions 62U are formed, semiconductor region 63U (alternatively referred to as a dummy semiconductor region) is simultaneously formed in trench 34. Accordingly, semiconductor region 63U is formed of the same semiconductor material as upper source/drain regions 62U. The top surface and the bottom surface of semiconductor region 63U may also be level with the top surfaces and the bottom surfaces, respectively, of upper source/drain regions 62U.

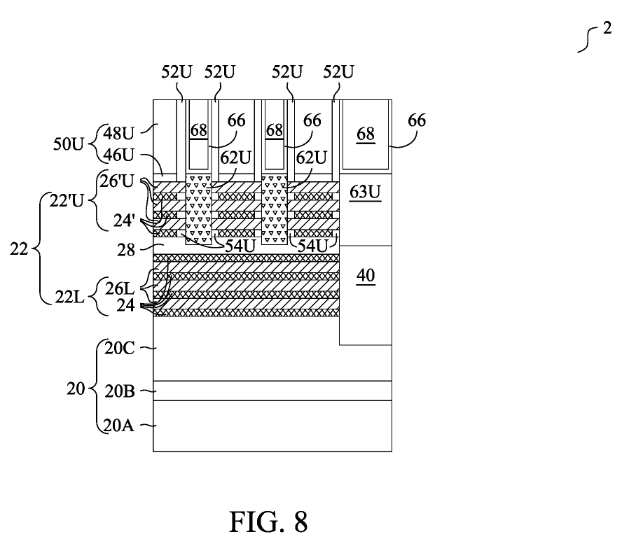

Referring to FIG. 8, a first contact etch stop layer (CESL) 66 and a first ILD 68 are formed. The respective process is illustrated as process 218 in the process flow 200 as shown in FIG. 19. The first CESL 66 may be formed of a dielectric material having a high etching selectivity for the etching of the first ILD 68. The first CESL 66 may be formed of or comprise silicon nitride, silicon oxide, silicon oxynitride, or the like, and may be formed by any suitable deposition process, such as CVD, ALD, or the like. The first ILD 68 may be formed of a dielectric material. The applicable dielectric material of the first ILD 68 may include phospho-silicate glass (PSG), boro-silicate glass (BSG), boron-doped phospho-silicate glass (BPSG), undoped silicate glass (USG), silicon oxide, or the like.

The formation processes may include depositing a conformal CESL layer, depositing a material for ILD, followed by a planarization process to level the top surfaces of the first CESL 66 and the first ILD 68 with the top surface of the dummy gate stack 50.

The dummy gate stacks 50U are then removed in one or more etching processes to form recesses. An additional isotropic etching process is then performed to remove dummy nanostructures 24’ and to extend the recesses into the spaces between semiconductor layers 26’U.

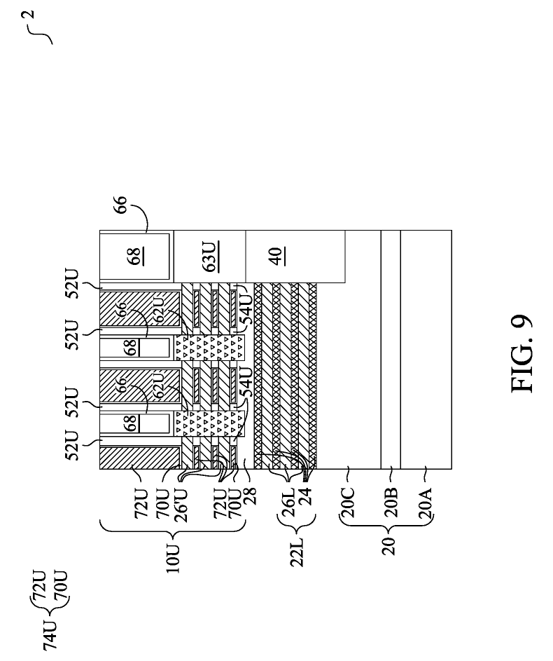

Referring to FIG. 9, replacement gate stacks 74U are formed in the recesses. The respective process is illustrated as process 220 in the process flow 200 as shown in FIG. 19. Upper FET 10U is thus formed. Replacement gate stacks 74U include gate dielectrics 70U and gate electrodes 72U. Each of gate dielectrics 70U may include an interfacial layer (such as a silicon oxide layer) and a high-k dielectric layer over the interfacial layer.

Gate electrodes 72U may comprise a plurality of conductive layers, which include work-function layers therein. The work-function layers may be selected to suit to the respective FET. For example, when the upper FETs are NFETs, the respective work-function layers are n-type work function layers having low work functions. When the upper FETs are PFETs, the respective work-function layers are p-type work function layers having high work functions.

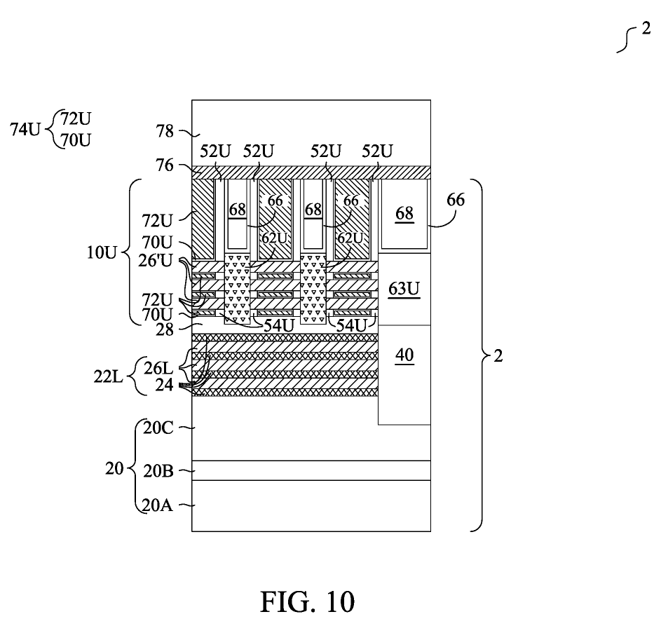

FIG. 10 illustrates the attachment of wafer 2 to carrier 78 through release film 76, which adheres carrier 78 to wafer 2. The respective process is illustrated as process 222 in the process flow 200 as shown in FIG. 19. Carrier 78 may be a glass carrier, a silicon wafer, an organic carrier, or the like. Release film 76 may be formed of a polymer-based material and/or an epoxy-based thermal-release material (such as a Light-To-Heat-Conversion (LTHC) material). Release film 76 is capable of being decomposed under radiation such as a laser beam, so that carrier 78 may be de-bonded from wafer 2.

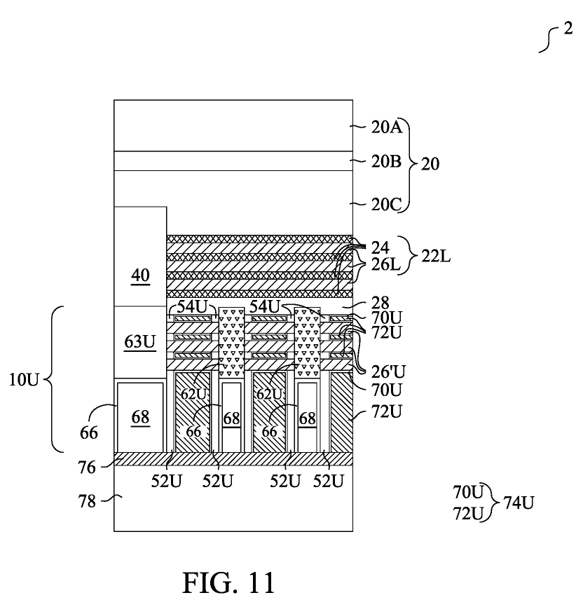

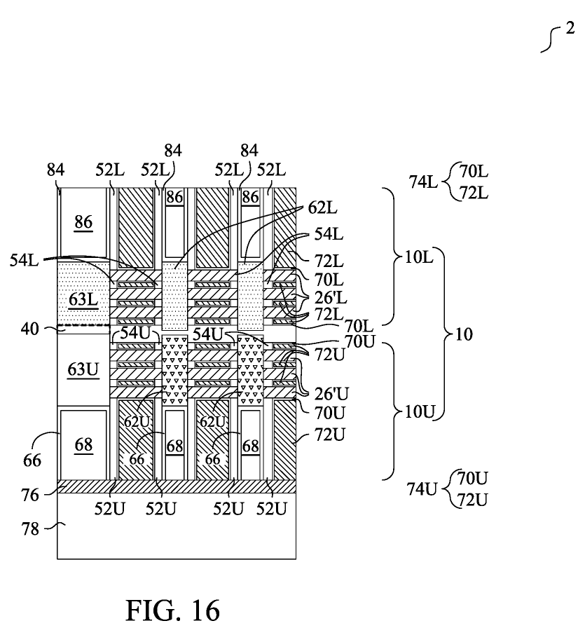

The structure shown in FIG. 10 is flipped upside down, and the resulting structure is shown in FIG. 11, which also illustrated by flipping left side to right than FIG. 16. The respective process is illustrated as process 224 in the process flow 200 as shown in FIG. 19.

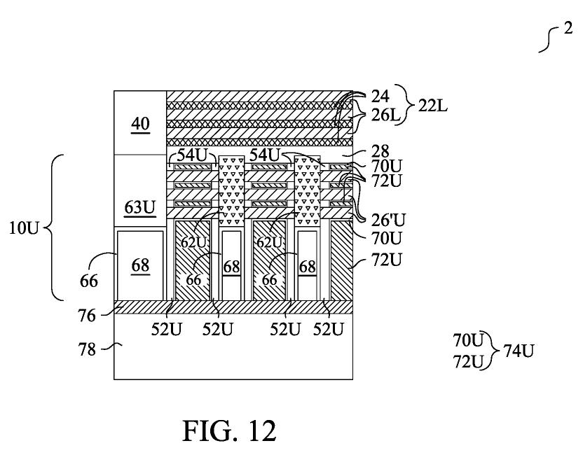

Next, a backside thinning process is performed to remove substrate 2o and to reveal dielectric region 40 and the lower multilayer stack 22L. The resulting structure is shown in FIG. 12. The respective process is illustrated as process 226 in the process flow 200 as shown in FIG. 19. The backside thinning process may be performed through a CMP process and/or an etching process. For example, a CMP process may be performed to remove semiconductor layer 20A, with stop layer 20B (FIG. 11) used as the CMP stop layer.

An etching process or another CMP process may then be performed to remove stop layer 20B and semiconductor layer 20C, with the etching/CMP process stopping on a dummy semiconductor layer 24. The exposed dummy semiconductor layer 24 is then removed, exposing an underlying semiconductor layer 26L.

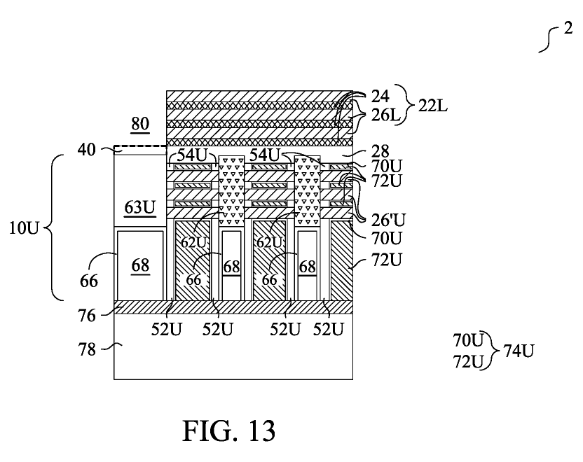

Referring to FIG. 13, an etching process is performed to etch and recess dielectric region 40, forming trench 80. The respective process is illustrated as process 228 in the process flow 200 as shown in FIG. 19. The etching process may be performed through an isotropic etching process using an etching chemical that etches dielectric region 40, but not lower multilayer stack portion 22L.

The bottom of trench 80 is level with or lower than the top surface of dielectric layer 28, so that the layers in lower multilayer stack 22L are exposed. In accordance with some embodiments, dielectric region 40 comprises a portion remaining after the etching process. In accordance with alternative embodiments, dielectric region 40 is fully removed, and semiconductor region 63U is exposed.

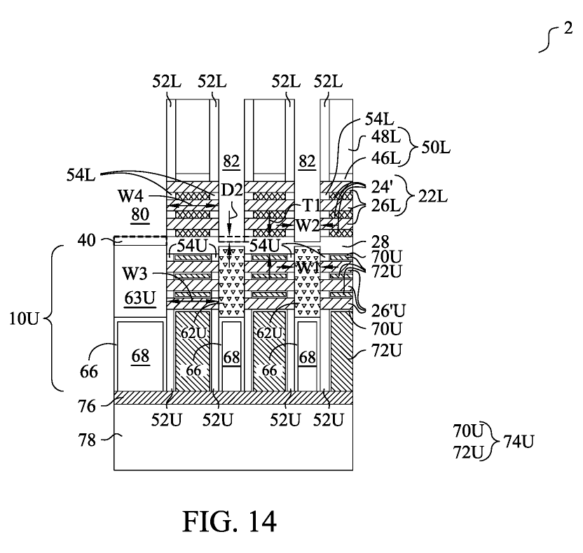

Next, as also shown in FIG. 14, lower multilayer stack 22L is patterned to form a plurality of multilayer stack portions 22’L. The respective process is illustrated as process 230 in the process flow 200 as shown in FIG. 19. The multilayer stack portions 22’L are protruding fins that protrude higher than dielectric layer 28. When viewed from the top of wafer 2, multilayer stack portions 22’L may form a plurality of elongated strips and hence are also referred to as patterned lower multilayer strips.

Further referring to FIG. 14, dummy gate stacks 50L are formed on the sidewalls and the top surfaces of the lower multilayer stack portions 22’L. The respective process is illustrated as process 232 in the process flow 200 as shown in FIG. 19. In accordance with some embodiments, dummy gate stacks 50L include dummy dielectric layer 46L on the protruding lower multilayer stack portion 22’L. Dummy dielectric layer 46L may be formed of or comprise, for example, silicon oxide, silicon nitride, a combination thereof, or the like, and may be deposited or thermally grown according to acceptable techniques.

Dummy gate layer 48L is formed over the dummy dielectric layer 46L, and may be formed of a material selected from the same group of candidate materials for forming dummy dielectric layer 46L.

While not shown, each dummy gate stack 50L may include a mask layer, which may be formed of silicon nitride, silicon oxynitride, or the like. A patterning process is performed to pattern the mask layer, the dummy gate layer 48L, and the dummy dielectric layer 46L. The remaining portions of the mask layer, dummy gate layer 48L, and dummy dielectric layer 46L form dummy gate stacks 50L.

As also shown in FIG. 14, gate spacers 52L are formed over the lower multilayer stack portions 22’L and on the exposed sidewalls of dummy gate stacks 50L. The gate spacers 52L may be formed by using processes and materials selected from the same groups of candidate processes and materials for forming dummy gate stacks 50L.

In a subsequent process, the lower multilayer stack portions 22’L is patterned to form lower source/drain recesses 82. The respective process is illustrated as process 234 in the process flow 200 as shown in FIG. 19. The resulting patterned lower multilayer stack portion 22’L is shown in FIG. 14. The top surface of dielectric layer 28 is also exposed through the gaps between neighboring lower multilayer stack portions 22’L. The protruding fins may have the shape of elongated strips when viewed in a top view of wafer 2.

The positions of at least some of the lower multilayer stack portions 22’L are accurately aligned to the positions of the underlying semiconductor layers 26’U. The alignment is achieved using trench 80, dielectric region 40, and/or semiconductor region 63 (when dielectric region 40 is fully removed) as the alignment mark. Both of the patterning of upper multilayer stack 22U (FIGS. 4 and 5) and the patterning of lower multilayer stack 22L (FIGS. 13 and 14) are performed using the features based on alignment trench 34 and the features formed therein as alignment mark. Accordingly, the lower multilayer stack portions 22’L are accurately aligned vertically to the underlying semiconductor layers 26’U.

The positions of the lower source/drain recesses 82 are also accurately aligned to the positions of (the underlying) upper source/drain regions 62U. The alignment is also achieved by using trench 80, dielectric region 40, and/or semiconductor region 63 as alignment marks. In accordance with some embodiments, the width W2 of lower source/drain recesses 82 is equal to width W1 of the respective underlying upper source/drain regions 62U. Also, the width W4 of semiconductor nanostructures 26’L may be equal to the width W3 of the respective underlying semiconductor nanostructures 26’U.

In accordance with alternative embodiments, the width W2 of lower source/drain recesses 82 may be greater than or smaller than the width W1 of the upper source/drain regions 62U. Accordingly, the width W4 of semiconductor nanostructures 26’L may be smaller than or greater than the width W3 of semiconductor nanostructures 26’U.

The etching of lower multilayer stack portion 22L may be performed through an anisotropic etching process using an etching mask (not shown), which may comprise a photoresist. The etching is performed using dielectric layer 28 as an etching stop layer. Due to the over-etching, lower source/drain recesses 82 extend into dielectric layer 28 for depth D2. The ratio D2/T1 may be in the range between about 0.05 and about 0.2, for example. After the etching process, etching mask 36 is removed.

In a subsequent process, dummy nanostructures 24’ are laterally recessed, and a dielectric material is filled into the respective recesses to form lower inner spacers 54L, which are dielectric spacers. The resulting structure is also shown in FIG. 14. The respective process is illustrated as process 236 in the process flow 200 as shown in FIG. 19.

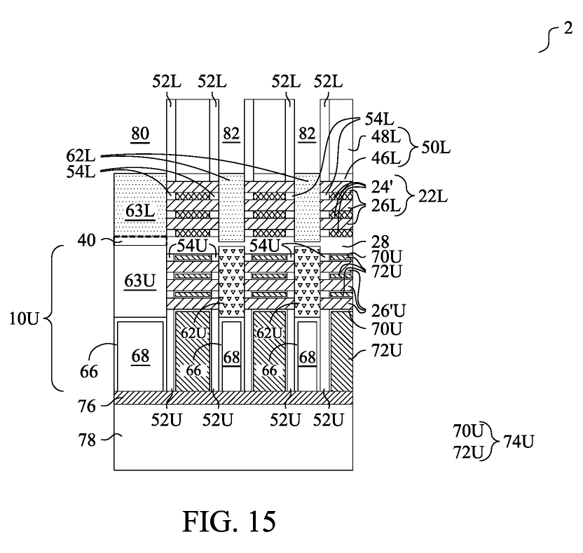

Referring to FIG. 15, lower source/drain regions 62L are formed in lower source/drain recesses 82. The respective process is illustrated as process 238 in the process flow 200 as shown in FIG. 19. The materials of lower source/drain regions 62L may be selected from the same candidate group of materials for forming upper source/drain regions 62U, depending on the desired conductivity type of lower source/drain regions 62L.

The conductivity type of the lower source/drain regions 62L may be opposite to the conductivity type of the upper epitaxial source/drain regions 62U. Alternatively stated, the lower source/drain regions 62L may be oppositely doped than the upper epitaxial source/drain regions 62U. The lower source/drain regions 62L may be in-situ doped, and/or may be implanted, with an n-type or p-type dopant.

At the time lower source/drain regions 62L are formed, semiconductor region 63L (alternatively referred to as a dummy semiconductor region) is formed in trench 80. Accordingly, semiconductor region 63L is formed of the same semiconductor material as, and has the same height as, the lower source/drain regions 62L. The bottom surface of semiconductor region 63L may also be level with, higher than, or lower than, the bottom surfaces of lower source/drain regions 62L, depending on how much recessing is performed in the process as shown in FIG. 13. The top surface of semiconductor region 63L may also be level with, higher, than, or lower than, the top surfaces of lower source/drain regions 62L.

In accordance with some embodiments in which semiconductor region 40 has a portion remaining, the semiconductor region 63L contacts the semiconductor region 40. In accordance with alternative embodiments in which semiconductor region 40 is fully removed, the semiconductor region 63L contacts upper semiconductor region 63U.

Next, as shown in FIG. 16, a second CESL 84 and a second ILD 86 are formed. The respective process is illustrated as process 240 in the process flow 200 as shown in FIG. 19. The materials and the formation methods may be similar to the materials and the formation methods of first CESL 66 and first ILD 68, respectively, and are not discussed in detail herein. After the planarization process, top surfaces of the second CESL 84, the second ILD 86, the gate spacers 52L, and the dummy gate stacks 50L are coplanar (within process variations).

The dummy gate stacks 50L are then removed in one or more etching processes to form recesses. An additional isotropic etching process is then performed to remove dummy nanostructures 24’ and to extend the recesses into the spaces between semiconductor layers 26’L.

Replacement gate stacks 74L are then formed. The respective process is illustrated as process 242 in the process flow 200 as shown in FIG. 19. Lower FET 10L is thus formed. Upper FET 10U and lower FET 10L collectively form CFET 10. Replacement gate stacks 74L include gate dielectrics 70L and gate electrodes 72L. Each of gate dielectrics 70L may include an interfacial layer (such as a silicon oxide layer) and a high-k dielectric layer over the interfacial layer.

Gate electrodes 72L may comprise a plurality of conductive layers, which include work-function layers therein. The work-function layers may be selected to suit to the respective FET. For example, when the lower FETs 10L are PFETs, the respective work-function layers are p-type work function layers having high work functions. When the lower FETs are NFETs, the respective work-function layers are n-type work function layers having low work functions.

FIG. 17 (illustrated upside down than FIG. 16) illustrates the formation of an example backside source/drain contact plug 88 connecting to upper source/drain regions 62U and lower source/drain regions 62L in accordance with some embodiments. Source/drain silicide layers (not shown) are also formed where source/drain contact plug 88 contact upper source/drain regions 62U and lower source/drain regions 62L. Backside contact plug 90 and metal lines 92 are then formed to form backside interconnect structure 93. More layers of routing may be formed on the backside of wafer 2, which layers of routing are not shown.

In a subsequent process, the carrier 78 (FIG. 16) is de-bonded from wafer 2, and wafer 2 is flipped upside down (as shown in FIG. 17) to form front-end-of-line routing structures (not shown) on the front side of the wafer 2.

In the CFET 10 as shown in FIG. 17, dielectric layer 28 separates lower FET 10L from upper FET 10U. Dielectric layer 28 may have thickness T1 between and vertically aligned to semiconductor layer 26’U and 26’L, and thickness T2 between and vertically aligned to upper source/drain regions 62U and lower source/drain regions 62L. Thickness T2 is smaller than thickness T1. Source/drain recesses extend from both of the upper side and the lower side of dielectric layer 28 into dielectric layer 28, and the upper source/drain regions 62U and lower source/drain regions 62L may have portions in the recesses. There may be, or may not be, remaining dielectric region 40 left in the final structure. Dielectric region 40, if remaining in the upper source/drain recesses, may be formed of a same dielectric material as, or a different dielectric material than, dielectric layer 28.

In accordance with some embodiments, semiconductor regions 63U and 63L are electrically floating. Semiconductor region 63U may be separated from semiconductor region 63L by dielectric region 40 or may be in physical contact with each other. Regardless of being electrically connected to each other or not, the combined region including semiconductor regions 63U and 63L, which combined region may or may not include remaining semiconductor region 40, are electrically floating.

In above-discussed processes, the lower FET 10L and upper FET 10U are formed in separate processes. Accordingly, the processes enable the upper FET 10U to be different from the lower FET 10L. For example, semiconductor nanostructure 26’U may be formed of a same or a different material from semiconductor nanostructure 26’L, for example, with one formed of germanium or SiGe, and the other formed of Si, as discussed precedingly. The thickness of semiconductor nanostructure 26’U may also be greater than, smaller than or equal to the thickness of semiconductor nanostructure 26’L. Also, the spacings (filled with replacement gate stacks 72U) between semiconductor nanostructure 26’U may be equal to, smaller than, or greater than the spacings (filled with replacement gate stacks 74L) between semiconductor nanostructure 26’L.

Also, as addressed above, the work-function layer of the upper FET 10U may be the different from, or the same as, the work-function layer of the lower FET 10L, for example, with one having an n-type work function, and the other having a p-type work function.

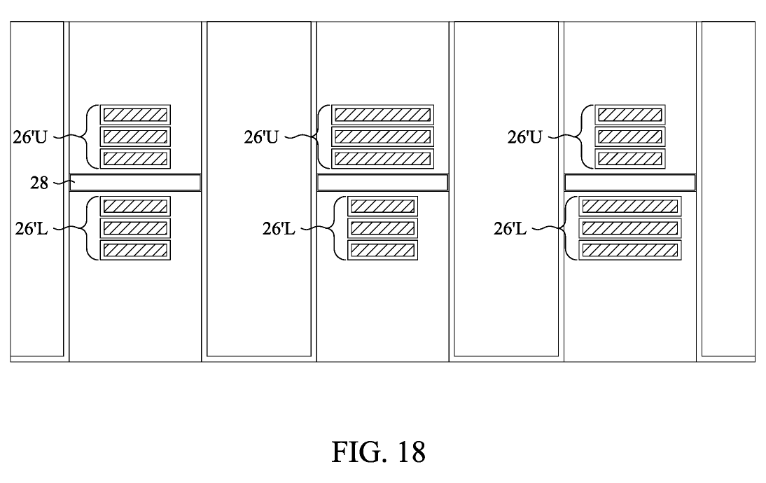

FIG. 18 schematically illustrate some portions of several CFETs that are formed in a same wafer (and a same device die) in accordance with some embodiments. FIG. 18 schematically illustrates a plurality of CFET in a same device die. The CFETs may have semiconductor nanostructure 26’U having width equal to, greater than, and smaller than, the width of the respective underlying semiconductor nanostructure 26’L. The cross-sectional views of these CFETs may be realized from the structure as shown in FIG. 17.

The embodiments of the present disclosure have some advantageous features. By forming upper FETs and lower FETs separately and from opposing directions of the respective wafer, the aspect ratios of source/drain regions are reduced since in each of the source/drain recesses, either upper the source/drain region or the lower source/drain region, but not both, is formed. The alignment mark is used to align the upper source/drain region to the lower source/drain region.

In accordance with some embodiments of the present disclosure, a method comprises forming a multilayer stack comprising: a lower multilayer stack over a substrate; a dielectric etch stop layer over the lower multilayer stack; and an upper multilayer stack over the dielectric etch stop layer; etching the multilayer stack to form an alignment mark trench; performing a first etching process on the upper multilayer stack to form upper multilayer stack portions, wherein the first etching process is performed using the dielectric etch stop layer to stop the first etching process, and wherein the first etching process is performed using the alignment mark trench for alignment; forming an upper transistor based on the upper multilayer stack portions; removing the substrate to reveal the lower multilayer stack; performing a second etching process on the lower multilayer stack to form lower multilayer stack portions, wherein the second etching process is performed using the dielectric etch stop layer to stop the second etching process, and wherein the second etching process is performed aligning to the alignment mark trench; and forming a lower transistor based on the lower multilayer stack portions.

In an embodiment, the second etching process is performed using the alignment mark trench for alignment. In an embodiment, the method further comprises forming a dielectric region in the alignment mark trench; and after the substrate is removed to reveal the lower multilayer stack, etching the dielectric region, wherein a portion of the dielectric region is left for alignment of the second etching process.

In an embodiment, the method further comprises forming a dielectric region in the alignment mark trench; epitaxially growing a semiconductor region over the dielectric region; and after the substrate is removed to reveal the lower multilayer stack, etching the dielectric region to reveal the semiconductor region. In an embodiment, the upper transistor comprises an upper source/drain region, and wherein a portion of the upper source/drain region is in the dielectric etch stop layer.

In an embodiment, the lower transistor comprises a lower source/drain region, and wherein a portion of the lower source/drain region is in the dielectric etch stop layer. In an embodiment, the method further comprises, after the first etching process, forming dielectric filling regions in spaces between the upper multilayer stack portions. In an embodiment, the method further comprises removing the dielectric filling regions and to re-generate the spaces between the upper multilayer stack portions. In an embodiment, the alignment mark trench further comprises a part in the substrate.

In accordance with some embodiments of the present disclosure, a method comprises etching a wafer to form an alignment mark trench that extends into an upper multilayer stack, a dielectric etch stop layer underlying the upper multilayer stack, and a lower multilayer stack underlying the dielectric etch stop layer; etching the upper multilayer stack to form a patterned upper multilayer stack; forming a first dielectric region in the alignment mark trench and second dielectric regions in upper spaces between the patterned upper multilayer stack; performing an etch-back process to recess the first dielectric region and the second dielectric regions; forming an upper gate stack over the patterned upper multilayer stack; forming upper source/drain regions in the upper spaces, wherein upper semiconductor layers in the patterned upper multilayer stack form first channels of an upper transistor; performing a backside thinning process to reveal the lower multilayer stack; etching the lower multilayer stack to form a patterned lower multilayer stack; forming a lower gate stack on the patterned lower multilayer stack; and forming lower source/drain regions in lower spaces between the patterned lower multilayer stack, wherein lower semiconductor layers in the patterned lower multilayer stack form second channels of a lower transistor.

In an embodiment, the etch-back process fully removes the second dielectric regions, and wherein the first dielectric region is partially removed. In an embodiment, the etching the upper multilayer stack to form the patterned upper multilayer stack is stopped on the dielectric etch stop layer. In an embodiment, the etching the lower multilayer stack to form the patterned lower multilayer stack is stopped on the dielectric etch stop layer. In an embodiment, the etching the upper multilayer stack to form the patterned upper multilayer stack and the etching the lower multilayer stack to form the patterned lower multilayer stack are performed using features formed based on the alignment mark trench for alignment.

In an embodiment, the method further comprises forming a contact plug penetrating through the dielectric etch stop layer to electrically interconnect one of the upper source/drain regions to one of the lower source/drain regions. In an embodiment, in the etch-back process, the second dielectric regions are partially removed. In an embodiment, in the etch-back process, the second dielectric regions are fully removed.

In accordance with some embodiments of the present disclosure, a structure comprises a dielectric layer; a first transistor overlying the dielectric layer, wherein the first transistor comprises: a first source/drain region comprising a first portion in the dielectric layer; and a first gate stack aside of the first source/drain region; and a second transistor underlying the dielectric layer, wherein the second transistor comprises: a second source/drain region comprising a second portion in the dielectric layer; and a second gate stack aside of the first source/drain region.

In an embodiment, the structure further comprises a first dummy semiconductor region and a second dummy semiconductor region, wherein the first dummy semiconductor region and the second dummy semiconductor region are at same levels as the first source/drain region and the second source/drain region, respectively. In an embodiment, the first transistor has a first channel region with a first width, and the second transistor has a second channel region with a second width different from the first width.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a wafer comprising a multilayer stack comprising:
a lower multilayer stack over a substrate;
a dielectric etch stop layer over the lower multilayer stack; and
an upper multilayer stack over the dielectric etch stop layer;
forming an upper transistor from a front side of the wafer, wherein the upper transistor is formed based on the upper multilayer stack;
forming an alignment mark extending from a top surface to a bottom surface of the multilayer stack; and
forming a lower transistor from a backside of the wafer, wherein the lower transistor is formed based on the lower multilayer stack, and wherein the lower transistor is formed using the alignment mark to align to the upper transistor.

2. The method of claim 1 further comprising:
etching the multilayer stack to form an alignment mark trench; and
performing an etching process on the upper multilayer stack to form upper multilayer stack portions, wherein the etching process is performed using the dielectric etch stop layer to stop the etching process, and wherein the etching process is performed using the alignment mark trench for alignment.

3. The method of claim 1 further comprising:
removing the substrate to reveal the lower multilayer stack; and
performing an etching process on the lower multilayer stack to form lower multilayer stack portions, wherein the etching process is performed using the dielectric etch stop layer to stop the etching process, and wherein the etching process is performed using the alignment mark for alignment.

4. The method of claim 1, wherein the alignment mark is formed by processes comprising:
etching the upper multilayer stack and the lower multilayer stack to form an alignment mark trench; and
filling the alignment mark trench to form a dielectric region.

5. The method of claim 4 further comprising recessing the dielectric region from the front side of the wafer to form a recess.

6. The method of claim 5, wherein the forming the upper transistor comprises forming a source/drain region, and wherein when the source/drain region is formed, a semiconductor material is deposited in the recess.

7. The method of claim 1 further comprising, before the lower transistor is formed, recessing the alignment mark from the backside of the wafer.

8. The method of claim 1, wherein the upper transistor comprises an upper source/drain region, and wherein a portion of the upper source/drain region is in the dielectric etch stop layer.

9. The method of claim 1, wherein the lower transistor comprises a lower source/drain region, and wherein a portion of the lower source/drain region is in the dielectric etch stop layer.

10. A method comprising:
etching a wafer to form an alignment mark trench that penetrates through an upper multilayer stack, a dielectric etch stop layer underlying the upper multilayer stack, and a lower multilayer stack underlying the dielectric etch stop layer;
etching the upper multilayer stack to form a patterned upper multilayer stack;
forming an upper transistor based on the patterned upper multilayer stack;
performing a backside thinning process to reveal the lower multilayer stack;
etching the lower multilayer stack to form a patterned lower multilayer stack; and
forming a lower transistor based on the patterned lower multilayer stack, wherein the lower transistor is formed using the features in the alignment mark trench for aligning to the upper transistor.

11. The method of claim 10, wherein the features in the alignment mark trench comprises a dielectric region.

12. The method of claim 10, wherein the features in the alignment mark trench comprises a semiconductor region.

13. The method of claim 12, wherein the features in the alignment mark trench comprises a same material as an upper source/drain region of the upper transistor.

14. The method of claim 12, wherein the features in the alignment mark trench comprises a same material as a lower source/drain region of the lower transistor.

15. A method comprising:
etching a wafer to form an alignment mark trench that penetrates through an upper multilayer stack, a dielectric etch stop layer underlying the upper multilayer stack, and a lower multilayer stack underlying the dielectric etch stop layer;
forming a dummy dielectric region in the alignment mark trench;
etching the upper multilayer stack to form a patterned upper multilayer stack;
forming an upper transistor based on the patterned upper multilayer stack, wherein the forming the upper transistor comprises:
epitaxially growing an upper source/drain region; and
when the upper source/drain region is grown, simultaneously depositing a first semiconductor material in the alignment mark trench;
performing a backside thinning process to reveal the lower multilayer stack;
etching the lower multilayer stack to form a patterned lower multilayer stack; and
forming a lower transistor based on the patterned lower multilayer stack, wherein the lower transistor is formed using features in the alignment mark trench for alignment.

16. The method of claim 15, wherein the forming the lower transistor comprise:
epitaxially growing a lower source/drain region; and
when the lower source/drain region is grown, simultaneously depositing a second semiconductor material in the alignment mark trench.

17. The method of claim 16 further comprising removing the dummy dielectric region, wherein the second semiconductor material is physically joined to the first semiconductor material.

18. The method of claim 16, wherein the second semiconductor material is separated from the first semiconductor material by the dummy dielectric region.

19. The method of claim 15, wherein the upper transistor is formed using features in the alignment mark trench for alignment.

20. The method of claim 15, wherein the lower transistor is forming using features in the alignment mark trench for alignment.
